(19) United States
(12) Patent Application Publication
(10) Pub. No.: US 2012/0306065 A1
(43) Pub. Date: Dec. 6, 2012

(54) SEMICONDUCTOR PACKAGE WITH PRE-SOLDERED GROOVES IN LEADS

(75) Inventor: Mohamad Ashraf Bin Mohd Arshad, Kuala Lumpur (MY)

(73) Assignee: TEXAS INSTRUMENTS INCORPORATED, Dallas, TX (US)

(21) Appl. No.: 13/151,500

(22) Filed: Jun. 2, 2011

(51) Int. Cl. H01L 23/495; H01L 21/78

(52) U.S. Cl. 257/676; 438/112; 257/E23.031; 257/E21.599

(57) ABSTRACT

A packaged semiconductor device includes a die pad on which a semiconductor die that includes a plurality of bond pads is attached. A plurality of lead terminals surround the die pad, wherein the plurality of bond pads are connected to the plurality of lead terminals, and the plurality of lead terminals include an outer toe-wall and a groove along their length that extends to the toe-wall to provide a lead terminal orifice. An encapsulating material that defines an outer dimension for the packaged semiconductor device is absent from the grooves. Solder fills the grooves. A bottomside of the solder in the grooves provides an exposed solder surface available for bonding.

### FIELD

Disclosed embodiments relate to packaged semiconductor devices and assembly processes, and more specifically semiconductor packages having leads structures for enhanced solder wetting.

### BACKGROUND

Semiconductor Small Outline No-Lead (SON) and Quad Flat No-Lead (QFN) devices are typically fabricated by assembling a plurality of semiconductor die on a metallic leadframe strip. The leadframe strip is laid out to include for each device the needed die pads and coordinated lead segments. In order to miniaturize the devices and conserve area in the layout of the leadframe strip, the layout is commonly designed so that the segments of one device are connected directly to the respective segments of the adjacent devices.

The majority of leadframes are made of a base metal such as copper or an alloy including copper, and plated with layers of solderable metal, such as a layer of nickel followed by a layer of palladium. After the die are assembled on the pads and wire bonded to the segments, the leadframe strip is encapsulated in a protective plastic compound while those segment areas intended for soldering are not covered by encapsulation compound. Subsequently, discrete devices are singulated from the leadframe strip by cutting through the encapsulation compound and the plated metal segments with a saw. As a consequence of the sawing step, the segments have a side surface where the base metal has been exposed by the saw. Finally, the discrete package devices are assembled on a substrate by solder-connecting the non-covered segment areas to metallic pads of the substrate.

### SUMMARY

Applicant has found in the assembly step of the packaged semiconductor devices to a substrate that solder wetting of the saw-exposed base metal of the lead at the cut line from singulation that becomes the “toe-end” of the lead is inconsistent and unreliable, such as for leadless packages including Small Outline No-Lead (SON) and Quad Flat No-Lead (QFN) packages. The root cause of this wetting problem has been found to be the exposed face being base metal material (e.g., uncoated copper) becoming oxidized due to susceptibility to oxidation, where the solder will not consistently wet the exposed surface during assembly to a substrate when an oxide layer forms (due to dry bake etc.), so that little or no solder fillet will form at the toe-end of the lead, and there may be no solder meniscus for a solder connection to a substrate. A solder meniscus is needed to confirm a reliable solder assembly to a substrate.

Applicant has recognized that flux generally has insufficient strength to remove the level of metal oxide (e.g., copper oxide) formed on the toe-end of the lead due to processes such as high temp package test (e.g., 150° C.), particularly over a prolonged period, and although copper oxide may be removable using mild acid it is generally not feasible to integrate an acid removal process into a surface mount (SMT) process. Applicant solved the problem of not being able to consistently create a solder meniscus upon assembly of packaged semiconductor devices to a substrate by forming one or more grooves, or furrows, into the leadframe segment surface while in strip form, and filling the lead grooves with solder before singulation (pre-soldering) of the leadframe strip to ensure formation of a side solder fillet on the toe-end of leadless packages, and to also help prevent metal (e.g., Cu) smearing upon singulation.

The solder filled grooves are positioned so that upon singulation the grooves in the leads extend to the “toe-end” of the lead. Upon solder assembly of the packaged semiconductor device to a substrate, the solder in the end of the groove allows solder wetting to form a meniscus visible to a top-view inspection. In addition, the enhanced solderable surfaces of the grooves add to the solderable surface area, thus increasing the solder assembly strength.

### BRIEF DESCRIPTION OF THE DRAWINGS

FIG. 1 is a flow chart that shows steps in an example method for fabricating packaged semiconductor devices including pre-soldering of grooves in the leads, according to an example embodiment.

FIG. 2A is a schematic bottom view of a strip portion of a plurality of packaged QFN/SON devices, wherein the terminals and the die pad surfaces intended for solder attachment remain un-encapsulated.

FIG. 2B depicts an enlarged bottom view of the individual terminals highlighted in FIG. 2A, showing the grooves in the terminals. The saw street is indicating the location of the cut by the singulation step.

FIG. 3A illustrates schematic cross sections and a schematic front view of a terminal with a groove according to an example embodiment.

FIG. 3B is a schematic cross section of the groove illustrated in FIG. 3A.

FIG. 3C illustrates an example packaged semiconductor device including solder filled grooves in the leads comprising a die pad on which a semiconductor die that includes a plurality of bond pads is attached by a die attach adhesive, according to an example embodiment.

FIG. 4 is a schematic cross sectional view of an example semiconductor assembly comprising the packaged semiconductor device shown in FIG. 3C assembled to a substrate, showing the distribution of the solder after the assembly, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

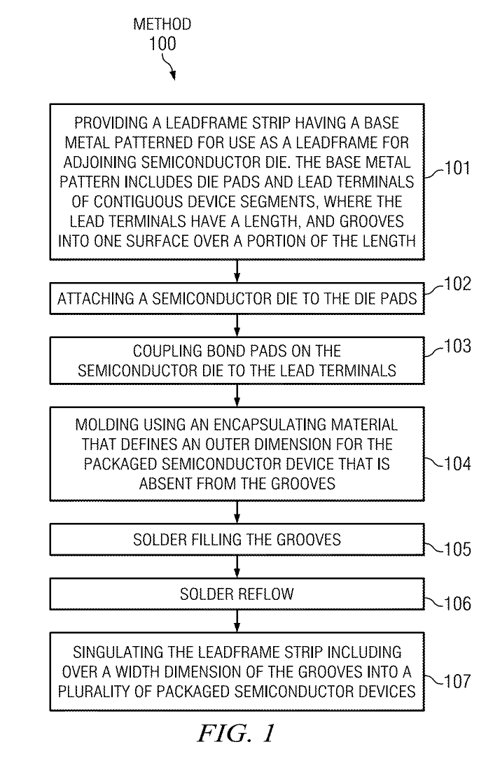

FIG. 1 is a flow chart that shows steps in an example method 100 for fabricating packaged semiconductor devices including pre-soldering of grooves in the leads, according to an example embodiment. Step 101 comprises providing a leadframe strip having a base metal patterned for use as a leadframe for adjoining semiconductor die. The base metal pattern includes die pads and lead terminals of contiguous device segments, where the lead terminals have a length, and grooves into one surface over a portion of the length.

The metallic leadframe strip has grooves in the leads that can be formed by a variety of methods. In one example method, a strip of a base metal sheet, such as copper or a copper alloy, is selected. At this stage, the strip may actually be long and processed in a reel-to-reel technique. The strip has two surfaces and may have a thickness in the range from 100 μm to 300 μm; the strip may be thicker or thinner. The strip is patterned, by a stamping or an etching technique, for the use as a leadframe in semiconductor devices. The patterned leadframe includes a plurality of adjoining structures for assembling semiconductor die and providing electrical leads of the assembled die to external parts. Included in the pattern are elongated leads of contiguous device segments; the leads have a certain length.

Grooves or furrows are formed into one of the surfaces of the elongated leads. This surface will later become the surface for contact or attachment to external parts. The grooves extend approximately over the length of the elongated leads and are thus also elongated. The grooves may have a depth of about 50 to 75% of the depth/thickness of the base metal strip and a cross section, which may be round or angled. Techniques of forming the elongated grooves include a mechanical stamping technique and a chemical etching technique. Alternatively, the grooves may be formed by a laser. The capability of each technique determines the groove width achievable. Each elongated lead should have at least one groove; however, if the lead width permits, more than one groove may be formed parallel to each other.

Step 102 comprises attaching semiconductor die to the die pads. One or more semiconductor die are attached to the die pad, and bond pads on the die are coupled to the leads. The assembly may use chip attachment and wire bonding, or flip-chip attachment.

Step 103 comprises coupling bond pads on the semiconductor die to the lead terminals. One example for face-up attached die comprises wire bonding. Another example arrangement comprises flip chip bonding. Step 104 comprises molding using an encapsulating material that defines an outer dimension for the packaged semiconductor device that is absent from the grooves. The encapsulating material is generally a polymer molding compound, so that the surface outer surface of the leads together with the lead grooves remains un-encapsulated. In this manner, the un-encapsulated leads of the leadframe can be accessed for electrical connection and, as described below, the lead segments can become the terminals of the encapsulated device.

Step 105 comprises solder filling the grooves, referred to herein as “pre-soldering” as it takes place before singulating the leadframe strip. Example solder filling processes include screen printing and dispensing. Step 106 comprises solder reflow. A solder reflow process helps ensure the solder solidifies and stays in the grooves throughout the remaining assembly processing described below.

Step 107 comprises singulating the leadframe strip including over a width dimension of the grooves into a plurality of packaged semiconductor devices. The solder remains in the grooves after singulating. The singulating can comprise sawing or punching. Alternatively, a laser may be used. The sawing proceeds along cut planes through the encapsulation compound and the leads. As a consequence, the leads are separated and become the terminals of discrete semiconductor devices, each terminals having at least one groove filled with solder. By the separation process, the base metal of the leads is exposed at the terminals face, which, in the case of copper, is easily oxidized; in addition, the solder filled orifice of the grooves is visible at the terminal face. Solder in the lead grooves helps prevent base metal (e.g., copper) from smearing over groove face.

In one alternative process flow, solder application into the grooves is performed prior to die-bond process and reflow performed right after. This alternative process thus skips solder reflow processing after the molding (encapsulating) process. Moreover, a solder-wettable surface can be added (e.g., plated) in the grooves before solder application. One particular example of a solder-wettable surface is nickel with an outermost layer of palladium/gold.

Disclosed embodiments thus solder coat the exposed metal (e.g., copper) area prior to shipping the packaged semiconductor devices, such as to a customer. The method can further comprise soldering the packaged semiconductor device to a substrate so that the lead terminals are attached by solder to contact pads on the substrate. The substrate can be an organic substrate. In one embodiment metal contact pads on the substrate have solder printed thereon.

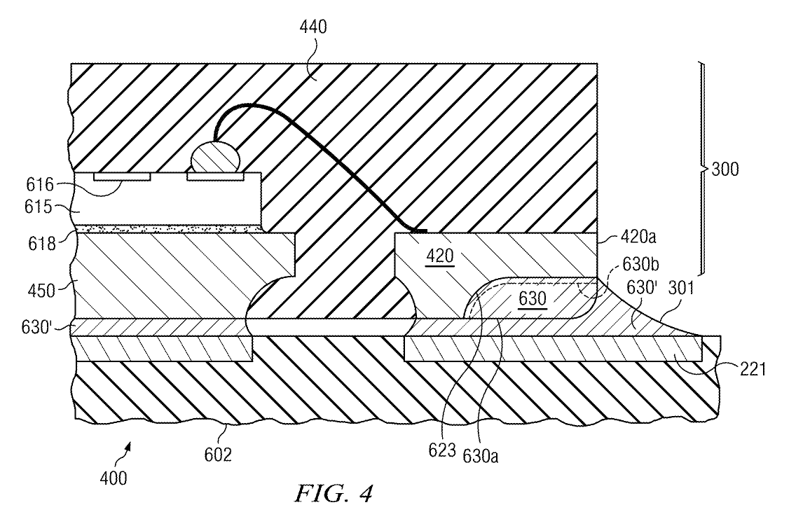

Upon reflowing, a low resistance solder connection is formed between the device terminals of the packaged semiconductor device and the contact pads on the substrate. Due to surface tension, along the contact are between the device terminals and metal pads solder protrudes to form a fillet with a meniscus surface from the outer edge of the package (see FIG. 4 described below). Thus, by having solder filled grooves, the solder can find a considerably enlarged area for the attachment grip and for solder volume than it can in devices with conventional flat terminal contact areas that do not exceed the footprint. The result is a significantly enhanced reliability of the attachment. Furthermore, as stated above, the solder is protruding from the orifice of the groove, forming a fillet with a meniscus surface along the substrate pad. The meniscus can be optically detected by process inspection, enhancing the quality assurance of the assembly step.

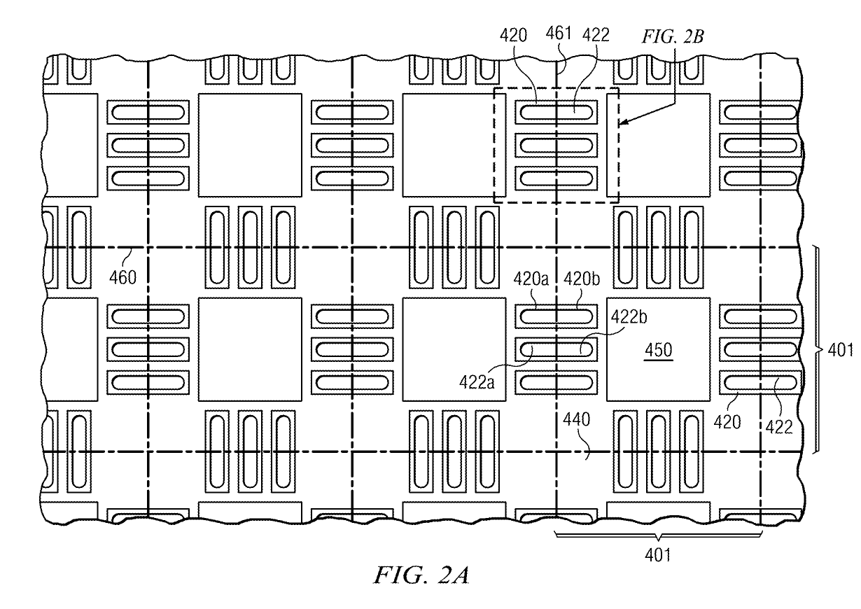

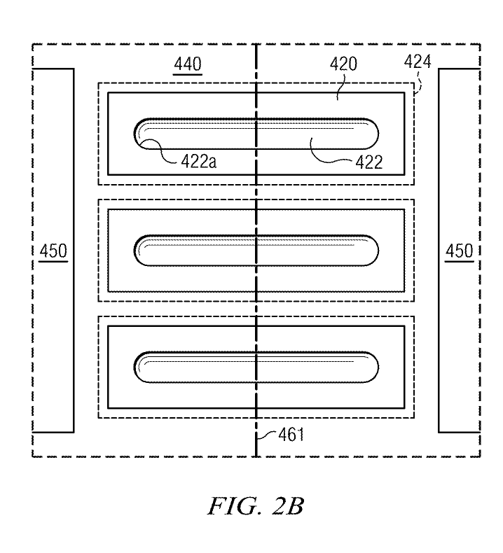

FIG. 2A is a schematic bottom view of a strip portion of a plurality of example packaged QFN/SON devices 401, wherein the terminals and the chip pad surfaces intended for solder attachment remain un-encapsulated. The encapsulation material 440 is a dielectric material, for instance a molding compound. In FIG. 2A, the terminals 420 of the devices are un-encapsulated to allow electrical contact to and physical connection with external parts. In addition, in this particular example, the die pads 450 remain free of encapsulation material 440 so that the thermal path from the attached chip to the eventual heat sink in the substrate is minimized. As FIG. 2A indicates, terminals 420 have an elongated shape with a certain length. The terminals have an oblong groove 422 (hereafter “groove”) fabricated into the terminal material from the bottom surface. The groove of each terminal 420 extends approximately over the length of the terminal. In some devices, there may be one or more terminals, which exhibit more than one groove. These grooves can be parallel to each other.

Further shown in FIG. 2A are dashed parallel cut lines 460, and dashed parallel cut lines 461. These lines indicate the cut lines (or saw street) for the saw in the singulation process of the strip. Cut lines 460 and lines 461 are oriented at right angles to each other. The cut lines are placed so that they sever the elongated terminals 420 together with the grooves 422 into two halves 420a and 420b. Since the two terminal halves originate from the elongated terminal 420, the two terminal halves 420a and 420b are contiguous. In analogous manner, the cut lines 460 and 461 sever the grooves 422 into two halves 422a and 422b. Since the two groove halves originate from the groove 422, the two groove halves 422a and 422b are contiguous.

A region of FIG. 2A marked by dashed outlines “FIG. 2B” is enlarged in FIG. 2B. In addition to terminals 420 and grooves 422, FIG. 2B illustrates a metal flange 424 for each terminal 420, which, in this view of the bottom surface, is hidden under the rim of the encapsulation material 440 (and therefore visible only in X-ray fashion and thus outlined in dashed contour). Flange 424 provides an anchor for the terminal in the encapsulation compound.

Referring now to the view of the bottom surface in FIG. 2B, the elongated structure of terminal 420 is echoed by the elongated structure of groove 422. The end portions 422a of groove 422 are shaped by the method of forming the groove (stamping or etching, see below). As examples, the end portions 422a may show a rounded contour, or a contour with corners, a slightly irregular contour, or any other outline.

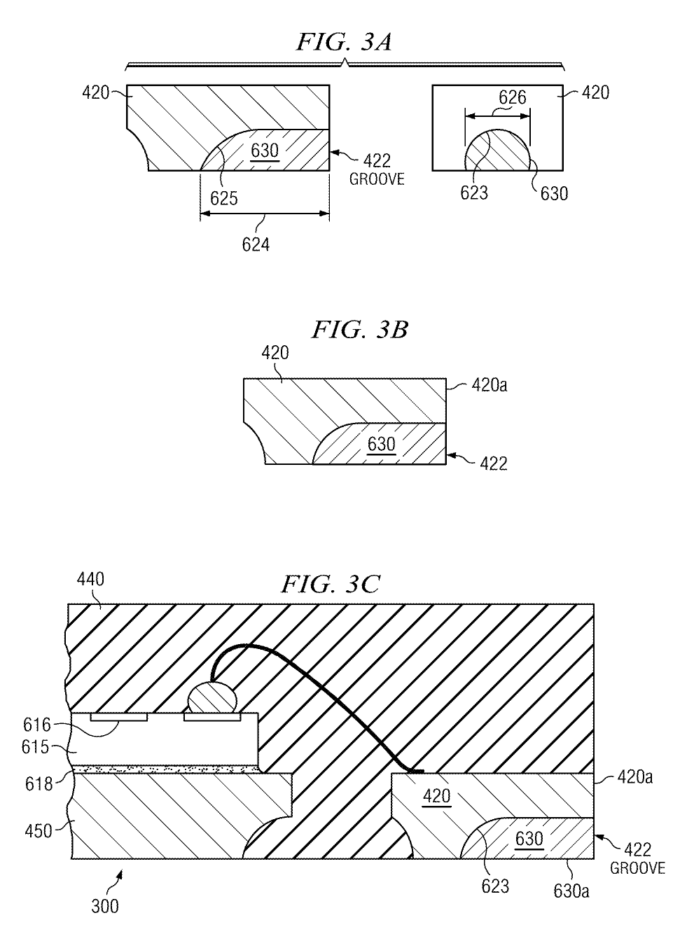

FIG. 3A shows a cross section of a terminal 420 with a groove 422 filled with solder 630 and the corresponding front view of the terminal 420 with the groove orifice 623 of the groove 422. FIG. 3B is a schematic cross section of the groove illustrated in FIG. 3A. In the fabrication process of the groove, the length 624 of groove 422 can be selected as suitable; also, the curvature 625 can be selected as suitable. In addition, the diameter (or other longest dimension) 626 of the groove 422 and its overall outline can be selected as suitable.

FIG. 3C illustrates a packaged semiconductor device 300 including solder filled grooves in the leads comprising a die pad 450 on which a semiconductor die 615 that includes a plurality of bond pads 616 is attached by a die attach adhesive 618, such as an epoxy comprising material. A plurality of lead terminals 420 surround the die pad 450 with a single lead terminal being shown. The plurality of bond pads 616 are connected to the plurality of lead terminals 420, and the plurality of lead terminals include a face 420a that defines an outer toe-wall, and a groove 422 along their length that extends to the toe-wall to provide a groove orifice 623 that is filled with solder 630.

An encapsulating material 440 defines an outer dimension for the packaged semiconductor device 300 that is absent from the grooves 422. A bottomside 630a of the solder 630 in the grooves 422 provides an exposed solder surface available for bonding.

FIG. 4 illustrates a schematic cross sectional view an example semiconductor assembly 400 comprising the example packaged semiconductor device 300 shown in FIG. 3C assembled to a substrate 602 using a soldering process, showing the distribution of the solder after the assembly. Solder from this soldering process is shown as 630′ since the solder composition from this solder process may be different as compared to the solder 630 in the grooves from disclosed pre-soldering.

In most soldering processes, although the well defined interface between solder 630 and solder 630′ shown in FIG. 4 may not be present after solder reflow, a band of solder material shown as 630b reflecting the composition of the solder 630 after soldering to the substrate 602 will generally be present along the interface with groove orifice 623 (e.g., due to surface tension), and thus differ in composition from the generally mixed solder composition away from the interface with the groove orifice 623. The solder distribution of solder in FIG. 4 is shown wetting the surface of what had been groove 422 and protruding from the groove orifice 623 as a meniscus 301 onto substrate pad 221 that will generally be visible to a top-view inspection. On the other hand, solder may not wet toe-wall/face 420a of terminal 420, since this surface exposes the base metal of the terminal, which may include copper and thus easily oxidize.

Disclosed embodiments can be integrated into a variety of assembly flows to form a variety of different semiconductor devices and related products. Disclosed assemblies can comprise single die or multiple die, such as PoP configurations comprising a plurality of stacked die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

I claim:

1. A packaged semiconductor device, comprising:
a die pad on which a semiconductor die that includes a plurality of bond pads is attached;
a plurality of lead terminals surrounding said die pad, wherein said plurality of bond pads are connected to said plurality of lead terminals, wherein said plurality of lead terminals include an outer toe-wall and a groove along their length that extends to said toe-wall to provide a lead terminal orifice;
an encapsulating material that defines an outer dimension for said packaged semiconductor device that is absent from said grooves, and
solder filling said grooves, wherein a bottomside of said solder in said grooves provides an exposed solder surface available for bonding.

2. The packaged semiconductor device of claim 1, wherein said packaged semiconductor device comprises a leadless package.

3. The packaged semiconductor device of claim 2, wherein said leadless package comprises a Small Outline No-Lead (SON) or a Quad Flat No-Lead (QFN) package.

4. The packaged semiconductor device of claim 1, wherein said plurality of lead terminals comprise copper.

5. The packaged semiconductor device of claim 1, further comprising a substrate having contact pads unto which said plurality of lead terminals are attached by solder, wherein a solder meniscus is between said lead terminal orifices and said substrate.

6. The packaged semiconductor device of claim 1, wherein said grooves have a depth from fifty percent to seventy-five percent of a depth of said plurality of lead terminals.

7. A method for fabricating packaged semiconductor devices, comprising:
providing a leadframe strip having a base metal patterned for use as a leadframe for adjoining semiconductor die, said base metal pattern including die pads and lead terminals of contiguous device segments, said lead terminals having a length, and grooves into one surface over a portion of said length;
attaching said semiconductor die to said die pads;
coupling bond pads on said semiconductor die to said lead terminals;
molding using an encapsulating material that defines an outer dimension for said packaged semiconductor device that is absent from said grooves,
solder filling said grooves, and
singulating said leadframe strip including over a width dimension of said grooves into a plurality of packaged semiconductor devices, wherein said solder remains in said grooves after said singulating.

8. The method of claim 7, wherein said solder filling comprises screen printing or dispensing.

9. The method of claim 7, further comprising solder reflow after said solder filling and before said singulating.

10. The method of claim 7, further comprising wherein said coupling comprises wire bonding.

11. The method of claim 7, wherein said packaged semiconductor device comprises a leadless package.

12. The method of claim 11, wherein said leadless package comprises a Small Outline No-Lead (SON) or a Quad Flat No-Lead (QFN) package.

13. The method of claim 7, further comprising soldering said packaged semiconductor device to a substrate so that said plurality of lead terminals are attached by solder to contact pads on said substrate, wherein a solder meniscus is between said lead terminal orifices and said substrate.

14. A semiconductor assembly, comprising:
a packaged semiconductor device, including:
a die pad on which a semiconductor die that includes a plurality of bond pads is attached;
a plurality of lead terminals surrounding said die pad, wherein said plurality of bond pads are connected to said plurality of lead terminals, wherein said plurality of lead terminals include an outer toe-wall and a groove along their length that extends to said toe-wall to provide a lead terminal orifice;
an encapsulating material that defines an outer dimension for said packaged semiconductor device that is absent from said grooves, and
solder filling said grooves, wherein a bottomside of said solder in said grooves provides an exposed solder surface available for bonding, and
a substrate having contact pads unto which said plurality of lead terminals are attached by solder, wherein a solder meniscus is between said lead terminal orifices and said substrate.

15. The semiconductor assembly of claim 14, wherein said packaged semiconductor device comprises a leadless package.

16. The semiconductor assembly of claim 15, wherein said leadless package comprises a Small Outline No-Lead (SON) or a Quad Flat No-Lead (QFN) package.
